(19) United States
(12) Patent Application Publication
(10) Pub. No.: US 2012/0274431 A1
(43) Pub. Date: Nov. 1, 2012

(54) TRANSFORMER HAVING HIGH DEGREE OF COUPLING, ELECTRONIC CIRCUIT, AND ELECTRONIC DEVICE

(75) Inventors: Noboru KATO, Nagaokakyo-shi (JP); Kenichi ISHIZUKA, Nagaokakyo-shi (JP)

(73) Assignee: MURATA MANUFACTURING CO., LTD., Nagaokakyo-shi (JP)

(21) Appl. No.: 13/546,007

(22) Filed: Jul. 11, 2012

Related U.S. Application Data
(63) Continuation of application No. PCT/JP2011/050886, filed on Jan. 19, 2011.

(30) Foreign Application Priority Data
Jan. 19, 2010 (JP) 2010-009513
Apr. 21, 2010 (JP) 2010-098312
Apr. 21, 2010 (JP) 2010-098313
Aug. 11, 2010 (JP) 2010-180088
Sep. 17, 2010 (JP) 2010-209295
Jan. 19, 2011 (JP) 2011-008535

(51) Int. Cl. H01F 27/28

(52) U.S. Cl. 336/182

(57) ABSTRACT

A transformer having a high degree of coupling is connected between, for example, an antenna element and a power feed circuit. The transformer having a high degree of coupling includes a first inductance element connected to the power feed circuit and a second inductance element coupled to the first inductance element. A first end of the first inductance element is connected to the power feed circuit and a second end of the first inductance element is connected to the antenna element. A first end of the second inductance element is connected to the antenna element and a second end of the second inductance element is grounded.

### BACKGROUND OF THE INVENTION

1. Field of the Invention

The present invention relates to a transformer having a high degree of coupling in which inductance elements are coupled to each other with a high degree of coupling and an electronic circuit and an electronic device that include the transformer having a high degree of coupling.

2. Description of the Related Art

Transformers generally include primary coils and secondary coils that are magnetically coupled to each other via magnetic paths. The transformers are widely used in various electronic circuits and electronic devices, such as voltage step-up and step-down circuits, transformers having a high degree of coupling, current transformation and shunt circuits, balance-unbalance conversion circuits, and signal transmission circuits.

In order to reduce the loss in transmission energy in the transformers, it is necessary to increase the degree of coupling between the primary coils and the secondary coils. For this purpose, methods of winding the primary coils and the secondary coils around ferrite magnetic bodies commonly used for the primary coils and the secondary coils have been adopted, for example, as described in Japanese Unexamined Patent Application Publication No. 10-294218 and Japanese Unexamined Patent Application Publication No. 2002-203721.

However, since lead wires are wound around the ferrite magnetic bodies to form the coils in the transformers disclosed in Japanese Unexamined Patent Application Publication No. 10-294218 and Japanese Unexamined Patent Application Publication No. 2002-203721, the manufacturing processes are complicated and the transformers are increased in size.

### SUMMARY OF THE INVENTION

In view of the above-described problems, preferred embodiments of the present invention provide a transformer having a high degree of coupling that is easy to manufacture, that is easy to be reduced in size, and that is capable of transmitting energy with significantly lower loss.

A transformer having a high degree of coupling according to a preferred embodiment of the present invention includes a first inductance element and a second inductance element coupled to the first inductance element with a high degree of coupling. The first inductance element is coupled to the second inductance element via a magnetic field and an electric field. When alternating current flows through the first inductance element, the direction of current flowing through the second inductance element due to the coupling via the magnetic field coincides with the direction of current flowing through the second inductance element due to the coupling via the electric field.

When alternating current flows through the first inductance element, the direction of current flowing through the second inductance element is preferably the direction along which a magnetic barrier occurs between the first inductance element and the second inductance element.

The first inductance element preferably includes a first coil element and a second coil element and the first coil element is preferably connected in series to the second coil element and winding patterns of conductors of the first coil element and the second coil element are preferably arranged to define a closed magnetic circuit.

Preferably, the second inductance element includes a third coil element and a fourth coil element and the third coil element is connected in series to the fourth coil element and winding patterns of conductors of the third coil element and the fourth coil element are arranged to define a closed magnetic circuit.

The first inductance element preferably includes a first coil element and a second coil element and the first coil element is preferably connected in series to the second coil element and winding patterns of conductors of the first coil element and the second coil element are preferably arranged to define a closed magnetic circuit. It is also preferable that the second inductance element includes a third coil element and a fourth coil element and that the third coil element is connected in series to the fourth coil element and winding patterns of conductors of the third coil element and the fourth coil element are arranged to define a closed magnetic circuit. It is also preferable that the first coil element and the third coil element be arranged such that an opening of the first coil element opposes an opening of the third coil element, and that the second coil element and the fourth coil element be arranged such that an opening of the second coil element opposes an opening of the fourth coil element.

The first inductance element and the second inductance element preferably include conductor patterns arranged in a multilayer body in which a plurality of dielectric or magnetic layers is laminated, and the first inductance element is preferably coupled to the second inductance element in the multilayer body.

An electronic circuit according to a preferred embodiment of the present invention includes a transformer having a high degree of coupling including a first inductance element and a second inductance element coupled to the first inductance element with a high degree of coupling, wherein the first inductance element is coupled to the second inductance element via a magnetic field and an electric field, and wherein, when alternating current flows through the first inductance element, the direction of current flowing through the second inductance element due to the coupling via the magnetic field coincides with the direction of current flowing through the second inductance element due to the coupling via the electric field; a primary side circuit connected to the first inductance element; and a secondary side circuit connected to the second inductance element.

An electronic device according to a preferred embodiment of the present invention includes a transformer having a high degree of coupling including a first inductance element and a second inductance element coupled to the first inductance element with a high degree of coupling, wherein the first inductance element is coupled to the second inductance element via a magnetic field and an electric field, and wherein, when alternating current flows through the first inductance element, the direction of current flowing through the second inductance element due to the coupling via the magnetic field coincides with the direction of current flowing through the second inductance element due to the coupling via the electric field; a primary side circuit connected to the first inductance element; a secondary side circuit connected to the second inductance element; and a circuit that transfers a signal or power between the primary side circuit and the secondary side circuit via the transformer having a high degree of coupling.

According to the transformer having a high degree of coupling of a preferred embodiment of the present invention, the primary side circuit connected to the first inductance element can be coupled to the secondary side circuit connected to the second inductance element with a high degree of coupling, for example, with a degree of coupling k being equal to about 1.2 or higher, which is not normally achieved. Accordingly, it is possible to reduce the transformer in size and, furthermore, to reduce the size of the electronic circuit and the electronic device including the transformer.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a circuit diagram of a transformer having a high degree of coupling of a first preferred embodiment of the present invention.

FIG. 2A is a more specific circuit diagram of the transformer having a high degree of coupling shown in FIG. 1 and FIG. 2B specifically shows the arrangement of coil elements in the transformer having a high degree of coupling.

FIG. 3 is a circuit diagram of an antenna apparatus 102 in which the transformer having a high degree of coupling 35 shown in the first preferred embodiment is applied as a transformer having a high degree of coupling for the antenna.

FIG. 4 is an equivalent circuit diagram of the antenna apparatus 102.

FIG. 5 is a circuit diagram of the antenna apparatus 102 supporting multiband operation.

FIG. 6A is a perspective view of the transformer having a high degree of coupling 35 of a third preferred embodiment of the present invention and FIG. 6B is a perspective view viewed from the bottom surface side of the transformer having a high degree of coupling 35.

FIG. 7 is an exploded perspective view of a multilayer body 40 of the transformer having a high degree of coupling 35.

FIG. 8 shows the principle of the operation of the transformer having a high degree of coupling 35.

FIG. 9 is a circuit diagram of a transformer having a high degree of coupling 34 of a fourth preferred embodiment of the present invention and an antenna apparatus 104 including the transformer having a high degree of coupling 34.

FIG. 10 is an exploded perspective view of a multilayer body 40 of the transformer having a high degree of coupling 34.

FIG. 11A is a perspective view of a transformer having a high degree of coupling 135 of a fifth preferred embodiment of the present invention and FIG. 11B is a perspective view of the transformer having a high degree of coupling 135, viewed from the bottom side thereof.

FIG. 12 is an exploded perspective view of a multilayer body 140 of the transformer having a high degree of coupling 135.

FIG. 13A is a circuit diagram of an antenna apparatus 106 of a sixth preferred embodiment of the present invention and FIG. 13B specifically shows the arrangement of coil elements in the antenna apparatus 106.

FIG. 14A shows a transformation ratio of the transformer having a high degree of coupling 35 and negative inductance components connected to the antenna element on the basis of the equivalent circuit shown in FIG. 13B. FIG. 14B is a diagram in which various arrows indicating how the magnetic field coupling and the electric field coupling are performed are added to the circuit in FIG. 13B.

FIG. 15 is a circuit diagram of the antenna apparatus 106 supporting multiband operation.

FIG. 16 shows exemplary conductor patterns of layers in a case in which the transformer having a high degree of coupling 35 according to a seventh preferred embodiment of the present invention is included in a multilayer board.

FIG. 17 shows main magnetic fluxes passing through the coil elements including the conductor patterns provided on the respective layers of the multilayer board shown in FIG. 16.

FIG. 18 shows the relationship of the magnetic coupling between four coil elements L1a, L1b, L2a, and L2b of the transformer having a high degree of coupling 35 according to the seventh preferred embodiment of the present invention.

FIG. 19 shows the configuration of a transformer having a high degree of coupling according to an eighth preferred embodiment of the present invention and shows exemplary conductor patterns of layers in a case in which the transformer having a high degree of coupling is provided in a multilayer board.

FIG. 20 shows main magnetic fluxes passing through the coil elements including the conductor patterns provided on the respective layers of the multilayer board shown in FIG. 19.

FIG. 21 shows the relationship of the magnetic coupling between the four coil elements L1a, L1b, L2a, and L2b of the transformer having a high degree of coupling according to the eighth preferred embodiment of the present invention.

FIG. 22 shows exemplary conductor patterns of the respective layers of a transformer having a high degree of coupling according to a ninth preferred embodiment of the present invention provided in a multilayer board.

FIG. 23 shows the relationship of the magnetic coupling between the four coil elements L1a, L1b, L2a, and L2b of the transformer having a high degree of coupling according to the ninth preferred embodiment of the present invention.

FIG. 24 is a circuit diagram of a transformer having a high degree of coupling according to a tenth preferred embodiment of the present invention.

FIG. 25 shows exemplary conductor patterns of layers in a case in which the transformer having a high degree of coupling according to the tenth preferred embodiment of the present invention is provided in a multilayer board.

FIG. 26 is a circuit diagram of a transformer having a high degree of coupling according to an eleventh preferred embodiment of the present invention.

FIG. 27 shows exemplary conductor patterns of layers in a case in which the transformer having a high degree of coupling according to the eleventh preferred embodiment of the present invention is provided in a multilayer board.

FIG. 28 is a circuit diagram of a transformer having a high degree of coupling according to a twelfth preferred embodiment of the present invention.

FIG. 29 shows exemplary conductor patterns of layers in a case in which the transformer having a high degree of coupling according to the twelfth preferred embodiment of the present invention is provided in a multilayer board.

FIG. 30A shows the configuration of a communication terminal apparatus of a first example of a thirteenth preferred embodiment of the present invention and FIG. 30B shows the configuration of a communication terminal apparatus of a second example of the thirteenth preferred embodiment of the present invention.

### DETAILED DESCRIPTION OF THE PREFERRED EMBODIMENTS

### First Preferred Embodiment

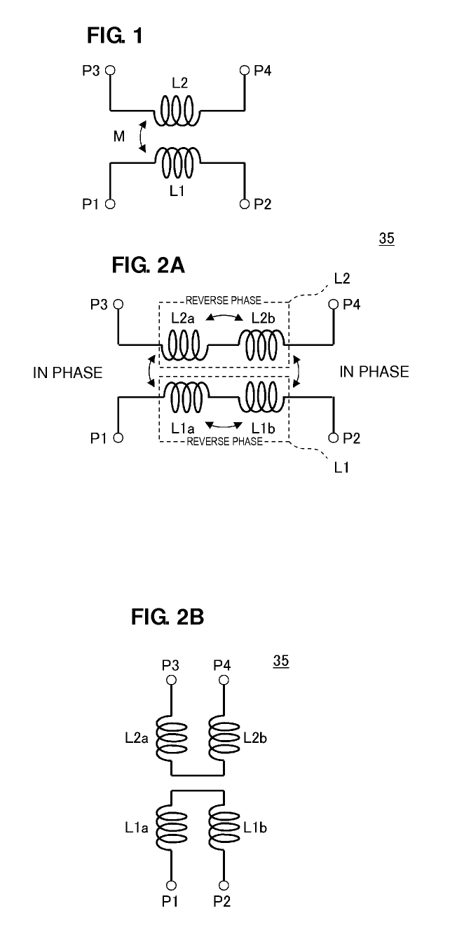

FIG. 1 is a circuit diagram of a transformer having a high degree of coupling of a first preferred embodiment.

As shown in FIG. 1, the transformer having a high degree of coupling includes a first inductance element L1 and a second inductance element L2 coupled to the first inductance element L1 with a high degree of coupling. A first end of the first inductance element L1 is preferably used as a first port P1 and a second end thereof is preferably used as a second port P2. A first end of the second inductance element L2 is preferably used as a third port P3 and a second end thereof is preferably used as a fourth port P4.

The first inductance element L1 is tightly coupled to the second inductance element L2.

FIG. 2A is a more specific circuit diagram of the transformer having a high degree of coupling shown in FIG. 1 and FIG. 2B specifically shows the arrangement of coil elements in the transformer having a high degree of coupling.

In a transformer having a high degree of coupling 35 shown in FIG. 2A, the first inductance element L1 includes a first coil element L1a and a second coil element L1b. The first coil element L1a and the second coil element L1b are connected in series to each other and are wound so as to define a closed magnetic circuit. The second inductance element L2 includes a third coil element L2a and a fourth coil element L2b. The third coil element L2a and the fourth coil element L2b are connected in series to each other and are wound so as to define a closed magnetic circuit. In other words, the first coil element La is coupled to the second coil element L1b in reverse phase (additive polarity coupling) and the third coil element L2a is coupled to the fourth coil element L2b in reverse phase (the additive polarity coupling).

In addition, the first coil element L1a is preferably coupled to the third coil element L2a in phase (subtractive polarity coupling) and the second coil element L1b is preferably coupled to the fourth coil element L2b in phase (the subtractive polarity coupling).

### Second Preferred Embodiment

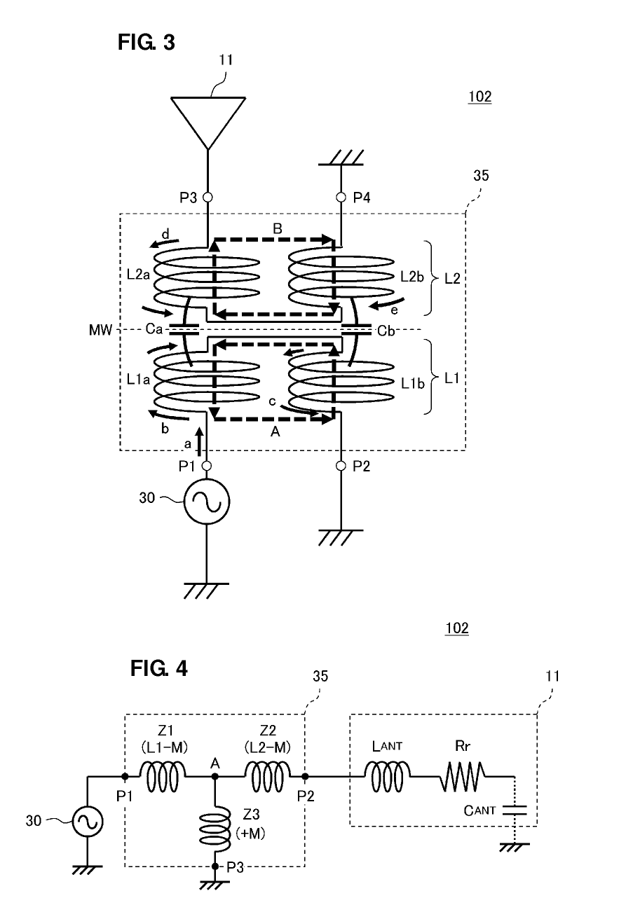

FIG. 3 is a circuit diagram of an antenna apparatus 102 in which the transformer having a high degree of coupling 35 shown in the first preferred embodiment is applied as a transformer having a high degree of coupling for the antenna.

As shown in FIG. 3, the antenna apparatus 102 includes an antenna element 11 and the transformer having a high degree of coupling 35 connected to the antenna element 11. The antenna element 11 preferably is a monopole antenna, and the transformer having a high degree of coupling 35 is connected to a power feed end of the antenna element 11. The transformer having a high degree of coupling 35 is provided between the antenna element 11 and a power feed circuit 30. The power feed circuit 30 supplies a radio-frequency signal to the antenna element 11. The power feed circuit 30 performs generation and processing of the radio-frequency signal. The power feed circuit 30 may include circuits that multiplex and demultiplex the radio-frequency signal.

As shown in FIG. 3, when current is supplied from the power feed circuit 30 in a direction shown by an arrow a, the current flows through the first coil element L1a in a direction shown by an arrow b and the current flows through the second coil element L1b in a direction shown by an arrow c. The currents form a magnetic flux passing through the closed magnetic circuit, as shown by an arrow A in FIG. 3.

Since the coil element L1a is lined with the coil element L2a, a magnetic field caused by the current b flowing through the coil element L1a is coupled to the coil element L2a to cause an induced current d to flow through the coil element L2a in a direction opposite to the direction of the current b. Similarly, since the coil element L1b is lined with the coil element L2b, a magnetic field caused by the current c flowing through the coil element L1b is coupled to the coil element L2b to cause an induced current e to flow through the coil element L2b in a direction opposite to the direction of the current c. The currents form a magnetic flux passing through the closed magnetic circuit, as shown by an arrow B in FIG. 3.

Since the closed magnetic circuit of the magnetic flux A occurring in the first inductance element L1 including the coil elements L1a and L1b is independent of the closed magnetic circuit of the magnetic flux B occurring in the second inductance element L2 including the coil elements L2a and L2b, an equivalent magnetic barrier MW occurs between the first inductance element L1 and the second inductance element L2.

The coil element L1a is coupled to the coil element L2a also via an electric field. Similarly, the coil element L1b is coupled to the coil element L2b also via an electric field. Accordingly, when alternating current flows through the coil element L1a and the coil element L1b, the current is excited in the coil element L2a and the coil element L2b by the electric field coupling. Capacitors Ca and Cb in FIG. 3 symbolically denote the coupling capacitances for the electric field coupling.

When the alternating current flows through the first inductance element L1, the direction of the current flowing through the second inductance element L2 due to the coupling via the magnetic field coincides with the direction of the current flowing through the second inductance element L2 due to the coupling via the electric field. Accordingly, the first inductance element L1 and the second inductance element L2 are tightly coupled to each other via both the magnetic field and the electric field. In other words, it is possible to propagate the radio-frequency energy with significantly reduced loss.

The transformer having a high degree of coupling 35 may also be referred to as a circuit configured such that, when the alternating current flows through the first inductance element L1, the direction of the current flowing through the second inductance element L2 due to the coupling via the magnetic field coincides with the direction of the current flowing through the second inductance element L2 due to the coupling via the electric field.

FIG. 4 is an equivalent circuit diagram of the antenna apparatus 102. As shown in FIG. 4, the antenna apparatus 102 equivalently includes an inductance component L^{ANT}, a radiation resistance component Rr, and a capacitance component C^{ANT}. The inductance component L^{ANT} of the antenna element 11 behaves so as to be offset by a negative added inductance (L2−M) in the transformer having a high degree of coupling 35. In other words, the inductance component (of the antenna element 11 including the second inductance element Z2) when the antenna element 11 side is viewed from an A point in the transformer having a high degree of coupling is small (ideally, is equal to zero) and, thus, impedance frequency characteristics of the antenna apparatus 102 are decreased.

In order to cause the negative inductance component, it is important to couple the first inductance element to the second inductance element with a high degree of coupling. Specifically, the degree of coupling should be higher than or equal to one.

An impedance conversion ratio in the transformer type circuit is indicated by the ratio (L1:L2) between the inductance L1 of the first inductance element L1 and the inductance L2 of the second inductance element L2.

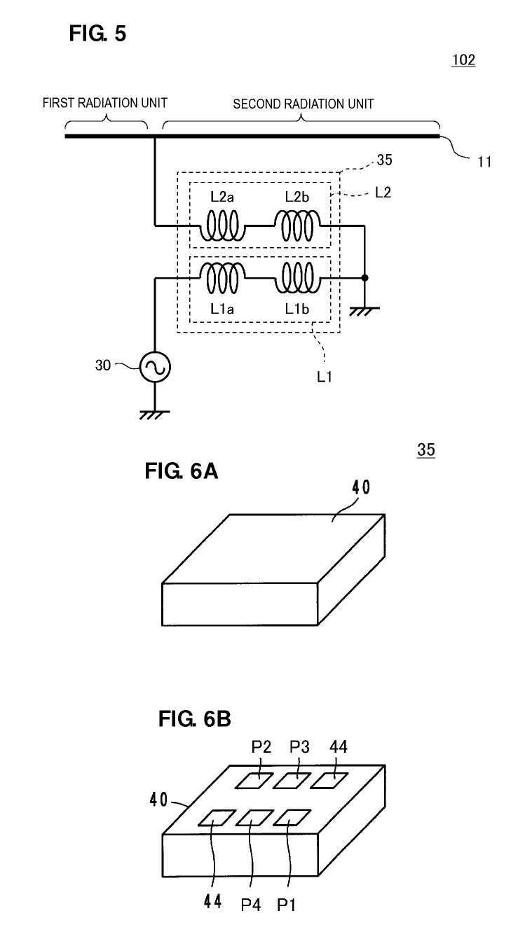

FIG. 5 is a circuit diagram of the antenna apparatus 102 supporting multiband operation. The antenna apparatus 102 is preferably for use in a multiband-supporting mobile radio communication system (an 800-MHz band, a 900-MHz band, a 1,800-MHz band, and a 1,900-MHz band) supporting a Global System for Mobile Communications (GSM) mode and a Code Division Multiple Access (CDMA) mode, for example. The antenna element 11 preferably is a branched monopole antenna.

### Third Preferred Embodiment

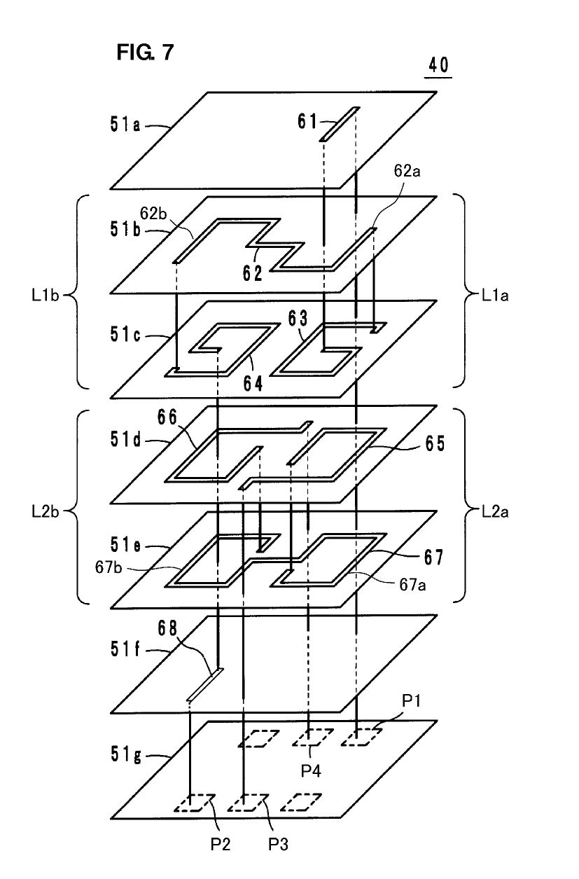

FIG. 6A is a perspective view of the transformer having a high degree of coupling 35 of a third preferred embodiment. FIG. 6B is a perspective view viewed from the bottom face side of the transformer having a high degree of coupling 35. FIG. 7 is an exploded perspective view of a multilayer body 40 defining the transformer having a high degree of coupling 35.

As shown in FIG. 7, a conductor pattern 61 is provided on a top base layer 51a of the multilayer body 40, a conductor pattern 62 (62a and 62b) is provided on a second base layer 51b thereof, conductor patterns 63 and 64 are provided on a third base layer 51c thereof. Conductor patterns 65 and 66 are provided on a fourth base layer 51d of the multilayer body 40 and a conductor pattern 67 (67a and 67b) is provided on a fifth base layer 51e thereof. In addition, a conductor pattern 68 is provided on a sixth base layer 51f of the multilayer body 40 and the ports P1, P2, P3, and P4 (that are connection terminals and that are hereinafter simply referred to as the ports) are provided on the rear surface of a seventh base layer 51g thereof. A plain base layer (not shown) is laminated on the top base layer 51a.

The conductor patterns 62a and 63 define the first coil element L1a and the conductor patterns 62b and 64 define the second coil element L1b. The conductor patterns 65 and 67a define the third coil element L2a and the conductor patterns 66 and 67b define the fourth coil element L2b.

The various conductor patterns 61 to 68 may be made of a material containing a conductive material, such as silver or copper, as the major component, for example. The base layers 51a to 51g may be made of, for example, a glass ceramic material or an epoxy based resin material, when the base layers 51a to 51g are formed of dielectric bodies, or may be made of, for example, a ferrite ceramic material or a resin material containing ferrite, when the base layers 51a to 51g are formed of magnetic bodies. In particular, a dielectric material is preferably used as the material of the base layers in order to form the transformer having a high degree of coupling for an Ultra High-Frequency (UHF) band and a magnetic material is preferably used as the material of the base layers in order to form the transformer having a high degree of coupling for a High-Frequency (HF) band.

Laminating the base layers 51a to 51g causes the conductor patterns 61 to 68 and the ports P1, P2, P3, and P4 to be connected to each other via inter-layer connection conductors (via conductors) to define the circuit shown in FIG. 3.

As shown in FIG. 7, the first coil element L1a is arranged adjacent to the second coil element L1b such that the winding axis of the coil pattern of the first coil element L1a is parallel or substantially parallel to that of the coil pattern of the second coil element L1b. Similarly, the third coil element L2a is arranged adjacent to the fourth coil element L2b such that the winding axis of the coil pattern of the third coil element L2a is parallel or substantially parallel to that of the coil pattern of the fourth coil element L2b. In addition, the first coil element L1a is arranged adjacent to the third coil element L2a such that the winding axis of the coil pattern of the first coil element L1a is aligned or substantially aligned with that of the coil pattern of the third coil element L2a (coaxial relationship). Similarly, the second coil element L1b is arranged adjacent to the fourth coil element L2b such that the winding axis of the coil pattern of the second coil element L1b is aligned or substantially aligned with that of the coil pattern of the fourth coil element L2b (coaxial relationship). Furthermore, the first to fourth coil elements L1a, L1b, L2a, and L2b are arranged such that an opening of the first coil element L1a opposes an opening of the third coil element L2a and an opening of the second coil element L1b opposes an opening of the fourth coil element L2b. In other words, the conductor patterns of the respective coil patterns are arranged so as to be overlaid with each other, viewed from the lamination direction of the base layers.

Although each of the coil elements L1a, L1b, L2a, and L2b preferably includes a substantially two-turn loop conductor, the number of turns is not limited to this. It is not necessary for the winding axes of the coil patterns of the first coil element L1a and the third coil element L2a to be strictly aligned with each other and it is sufficient for the first coil element L1a and the third coil element L2a to be wound such that the opening of the first coil element L1a coincides with that of the third coil element L2a in a planar view. Similarly, it is not necessary for the winding axes of the coil patterns of the second coil element L1b and the fourth coil element L2b to be strictly aligned with each other and it is sufficient for the second coil element L1b and the fourth coil element L2b to be wound such that the opening of the second coil element L1b coincides with that of the fourth coil element L2b in a planar view.

Incorporating the respective coil elements L1a, L1b, L2a, and L2b in the dielectric or magnetic multilayer body 40 in the above manner, in particular, providing an area where the first inductance element L1 including the coil elements L1a and L2b is coupled to the second inductance element L2 including the coil elements L2a and L2b in the multilayer body 40 causes the element values of the elements of the transformer having a high degree of coupling 35 and the degree of coupling between the first inductance element L1 and the second inductance element L2 to be less affected by other electronic devices arranged adjacent to the multilayer body 40. As a result, it is possible to further stabilize the frequency characteristics.

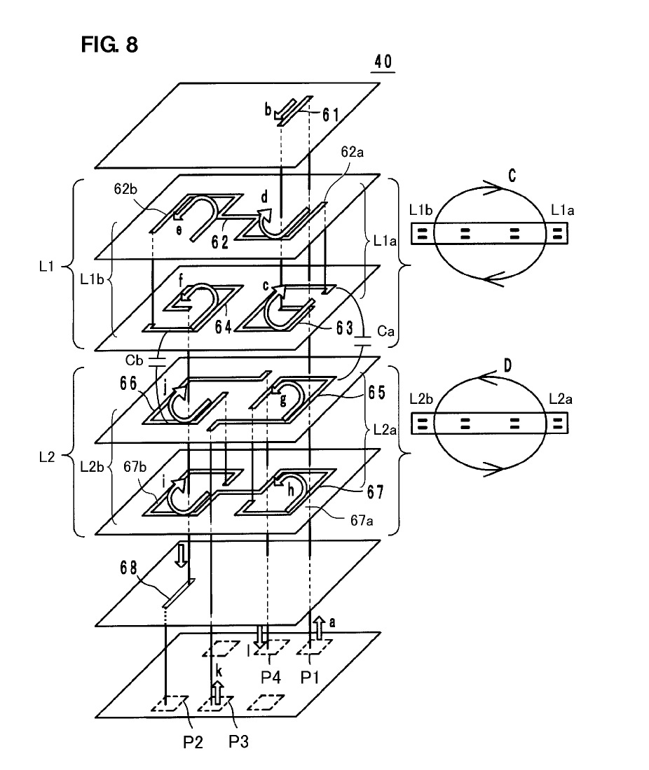

FIG. 8 shows the principle of the operation of the transformer having a high degree of coupling 35. As shown in FIG. 8, when a high-frequency signal current input through the port P1 flows in a manner shown by arrows a and b, the current is applied to the first coil element L1a (the conductor patterns 62a and 63) in a manner shown by arrows c and d and is applied to the second coil element L1b (the conductor patterns 62b and 64) in a manner shown by arrows e and f. Since the first coil element L1a (the conductor patterns 62a and 63) is lined with the third coil element L2a (the conductor patterns 65 and 67a), a high-frequency signal current shown by arrows g and h is induced in the third coil element L2a (the conductor patterns 65 and 67a) by the inductive coupling and the electric field coupling between the first coil element L1a and the third coil element L2a.

Similarly, since the second coil element L1b (the conductor pattern 62b and 64) is lined with the fourth coil element L2b (the conductor patterns 66 and 67b), a high-frequency signal current shown by arrows i and j is induced in the fourth coil element L2b (the conductor patterns 66 and 67b) by the inductive coupling and the electric field coupling between the second coil element L1b and the fourth coil element L2b.

As a result, a high-frequency signal current shown by an arrow k flows through the port P3 and a high-frequency signal current shown by an arrow 1 flows through the port P4. When the current (the arrow a) flowing through the port P1 is directed to an opposite direction, the direction of the other currents is made opposite.

Since the conductor pattern 63 of the first coil element L1a opposes the conductor pattern 65 of the third coil element L2a, the electric field coupling occurs between the conductor pattern 63 and the conductor pattern 65 and the current caused by the electric field coupling flows in the same direction as that of the induced current. In other words, the degree of coupling is increased by the magnetic field coupling and the electric field coupling. Similarly, the magnetic field coupling and the electric field coupling occur between the conductor pattern 64 of the second coil element L1b and the conductor pattern 66 of the fourth coil element L2b.

The first coil element L1a is coupled to the second coil element L1b in phase to define the closed magnetic circuit and the third coil element L2a is coupled to the fourth coil element L2b in phase to define the closed magnetic circuit. Accordingly, two magnetic fluxes C and D are generated to reduce the losses in energy between the first coil element L1a and the second coil element L1b and between the third coil element L2a and the fourth coil element L2b. Setting the inductance value of the first coil element L1a and that of the second coil element L1b to substantially the same element value and setting the inductance value of the third coil element L2a and that of the fourth coil element L2b to substantially the same element value reduce the leakage field of the closed magnetic circuits to further reduce the loss in energy. The element values of the coil elements may be appropriately designed to control the impedance conversion ratio.

Since the third coil element L2a is electrically coupled to the fourth coil element L2b with capacitors Cag and Cbg via the ground conductor 68, the current caused by the electric field coupling increases the degree of coupling between L2a and L2b. If the multilayer body 40 is grounded at the upper side, it is possible to cause the electric field coupling between the first coil element L1a and the second coil element L1b with the capacitors Cag and Cbg to further increase the degree of coupling between L1a and L1b.

The magnetic flux C excited by a primary current flowing through the first inductance element L1 and the magnetic flux D excited by a secondary current flowing through the second inductance element L2 occur so as to defeat (repel) each other because of the induced current. As a result, since the magnetic field occurring in the first coil element L1a and the second coil element L1b and the magnetic flux occurring in the third coil element L2a and the fourth coil element L2b are contained in narrow spaces, the first coil element L1a is coupled to the third coil element L2a with higher degree of coupling and the second coil element L1b is coupled to the fourth coil element L2b with higher degree of coupling. In other words, the first inductance element L1 is coupled to the second inductance element L2 with a high degree of coupling.

### Fourth Preferred Embodiment

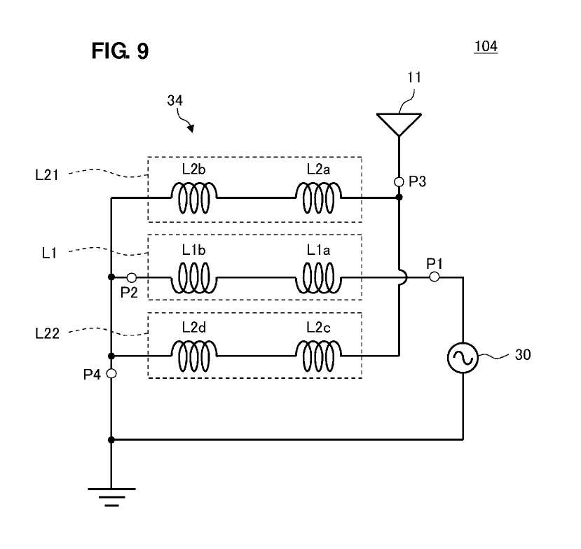

FIG. 9 is a circuit diagram of a transformer having a high degree of coupling 34 of a fourth preferred embodiment and an antenna apparatus 104 including the transformer having a high degree of coupling 34. The transformer having a high degree of coupling 34 included in the fourth preferred embodiment includes the first inductance element L1 and two second inductance elements L21 and L22. A fifth coil element L2c and a sixth coil element L2d of the second inductance element L22 are coupled to each other in phase. The fifth coil element L2c is coupled to the coil element L1a in reverse phase, and the sixth coil element L2d is coupled to the coil element L1b in reverse phase. One end of the fifth coil element L2c is connected to the radiation element 11 and one end of the sixth coil element L2d is grounded.

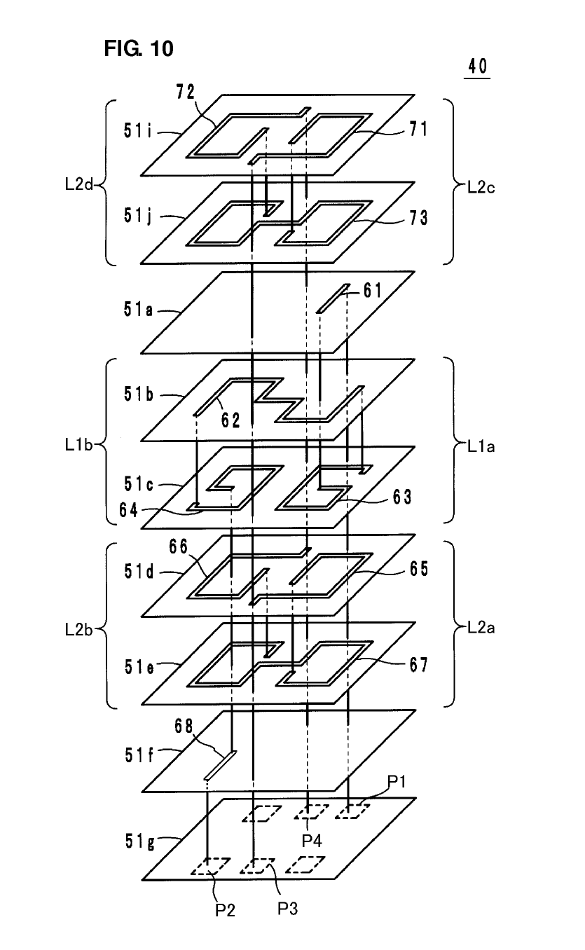

FIG. 10 is an exploded perspective view of the multilayer body 40 of the transformer having a high degree of coupling 34. In this example, base layers 51i and 51j on which conductors 71, 72, and 73 of the fifth coil element L2c and the sixth coil element L2d are provided are laminated on the multilayer body 40 of the third preferred embodiment shown in FIG. 7. Specifically, the fifth and sixth coil elements are configured preferably in the same manner as in the first to fourth coil elements described above, the fifth and sixth coil elements L2c and L2d are including the conductors of coil patterns, and the fifth and sixth coil elements L2c and L2d are wound so that the magnetic flux occurring in the fifth and sixth coil elements L2c and L2d defines the closed magnetic circuit.

The principle of the operation of the transformer having a high degree of coupling 34 of the fourth preferred embodiment is basically the same as that in the first to third preferred embodiments described above. In the fourth preferred embodiment, the first inductance element L1 is arranged so as to be sandwiched between the second inductance elements L21 and L22 to significantly reduce and prevent a stray capacitance occurring between the first inductance element L1 and the ground. The significant reduction and prevention of such a capacitance component that does not contribute to the radiation allows the radiation efficiency of the antenna to be improved.

In addition, since the first inductance element L1 is more tightly coupled to the second inductance elements L21 and L22, that is, the leakage field is reduced, the energy transmission loss of the radio-frequency signals between the first inductance element L1 and the second inductance elements L21 and L22 is reduced.

### Fifth Preferred Embodiment

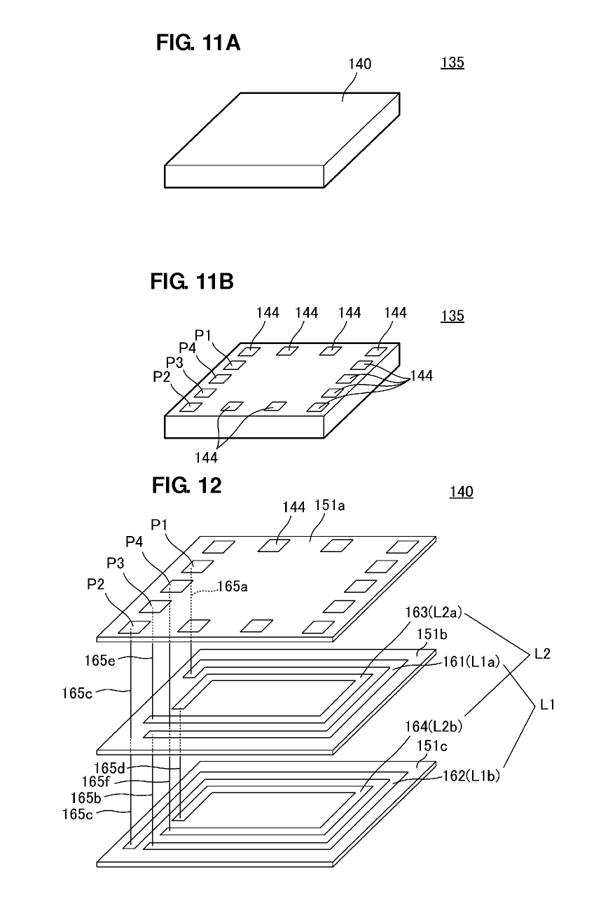

FIG. 11A is a perspective view of a transformer having a high degree of coupling 135 of a fifth preferred embodiment. FIG. 11B is a perspective view of the transformer having a high degree of coupling 135, viewed from the bottom side thereof. FIG. 12 is an exploded perspective view of a multilayer body 140 of the transformer having a high degree of coupling 135.

The multilayer body 140 includes multiple base layers laminated therein, which are preferably formed of dielectric bodies or magnetic bodies. The port P1 connected to the power feed circuit 30, the ports P2 and P4 that are grounded, and the port P3 connected to the antenna element 11 are provided on the rear surface of the multilayer body 140. A Normally Closed (NC) terminal used for mounting is also provided on the rear surface of the multilayer body 140. An inductor and/or a capacitor for impedance matching may be installed on the front surface of the multilayer body 140, if necessary. The inductor and/or the capacitor defined by an electrode pattern may be provided in the multilayer body 140.

In the transformer having a high degree of coupling 135 incorporated in the multilayer body 140, as illustrated in FIG. 12, the ports P1, P2, P3, and P4 are provided on a first base layer 151a, conductor patterns 161 and 163 defining the first and third coil elements L1a and L2a are provided on a second base layer 151b, and conductor patterns 162 and 164 defining the second and fourth coil elements L1b and L2b are provided on a third base layer 151c.

The conductor patterns 161 to 164 may be formed by, for example, screen printing of paste containing a conductive material, such as silver or copper, as the major component or etching on metal foils. The base layers 151a to 151c may be made of, for example, a glass ceramic material or an epoxy based resin material, when the base layers 151a to 151c are formed of dielectric bodies, or may be made of, for example, a ferrite ceramic material or a resin material containing ferrite, when the base layers 151a to 151c are formed of magnetic bodies.

Laminating the base layers 151a to 151c cause the conductor patterns 161 to 164 and the ports P1, P2, P3, and P4 to be connected to each other via inter-layer connection conductors (via hole conductors) to define the equivalent circuit shown in FIG. 2A. Specifically, the port P1 is connected to one end of the conductor pattern 161 (the first coil element L1a) via a via hole conductor 165a, and the other end of the conductor pattern 161 is connected to one end of the conductor pattern 162 (the second coil element L1b) via a via-hole conductor 165b. The other end of the conductor pattern 162 is connected to the port P2 via a via-hole conductor 165c, one end of the conductor pattern 164 (the fourth coil element L2b) is connected to one end of the conductor pattern 163 (the third coil element L2a) via a via-hole conductor 165d, and the other end of the conductor pattern 164 (the fourth coil element L2b) is connected to the port P4 via a via-hole conductor 165f. The other end of the conductor pattern 163 is connected to the port P3 via a via-hole conductor 165e.

Incorporating the respective coil elements L1a, L1b, L2a, and L2b in the dielectric or magnetic multilayer body 140 in the above manner, in particular, providing an area where the first inductance element L1 is coupled to the second inductance element L2 in the multilayer body 140 causes the transformer having a high degree of coupling 135 to be less affected by other circuits or devices arranged adjacent to the multilayer body 140. As a result, it is possible to further stabilize the frequency characteristics.

Providing the first coil element L1a and the third coil element L2a on the same layer (the base layer 151b) in the multilayer body 140 and providing the second coil element L1b and the fourth coil element L2b on the same layer (the base layer 151c) in the multilayer body 140 reduce the multilayer body 140 (the transformer having a high degree of coupling 135) in thickness. In addition, since it is possible to form the first coil element L1a and the third coil element L2a coupled to each other in the same process (for example, application of conductive paste) and to form the second coil element L1b and the fourth coil element L2b coupled to each other in the same process (for example, application of conductive paste), the variation in the degree of coupling caused by, for example, lamination shift is significantly reduced and prevented to improve the reliability.

### Sixth Preferred Embodiment

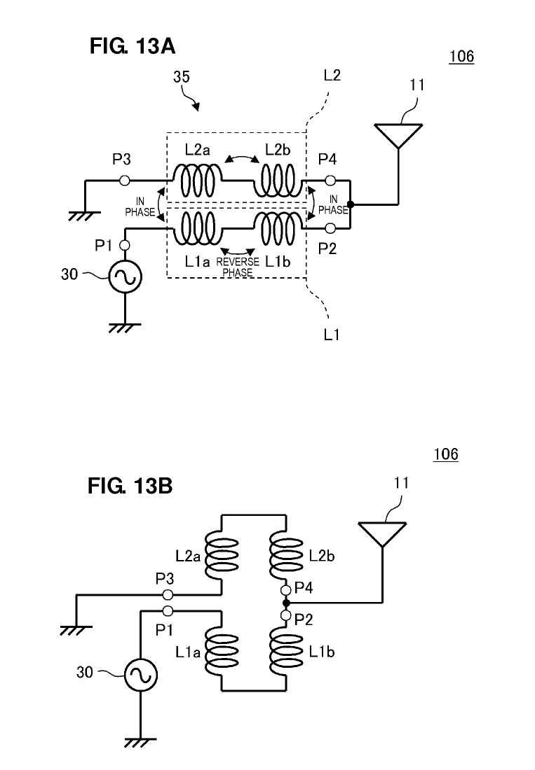

FIG. 13A is a circuit diagram of an antenna apparatus 106 of a sixth preferred embodiment and FIG. 13B specifically shows the arrangement of coil elements in the antenna apparatus 106.

Although the configuration of the transformer having a high degree of coupling provided in the antenna apparatus 106 of the sixth preferred embodiment is preferably the same as that in the first preferred embodiment, the transformer having a high degree of coupling of the sixth preferred embodiment differs from that of the first preferred embodiment in a manner of how the transformer having a high degree of coupling is connected to the respective ports. The example in the sixth preferred embodiment shows a connection structure that achieves a pseudo large negative inductance in the transformer having a high degree of coupling 35.

As illustrated in FIG. 13A, the first inductance element L1 includes the first coil element L1a and the second coil element L1b. The first coil element L1a and the second coil element L1b are connected in series to each other and are wound so as to define a closed magnetic circuit. The second inductance element L2 includes the third coil element L2a and the fourth coil element L2b. The third coil element L2a and the fourth coil element L2b are connected in series to each other and are wound so as to define a closed magnetic circuit. In other words, the first coil element L1a is coupled to the second coil element L1b in reverse phase (additive polarity coupling) and the third coil element L2a is coupled to the fourth coil element L2b in reverse phase (the additive polarity coupling).

In addition, the first coil element L1a is preferably coupled to the third coil element L2a in phase (subtractive polarity coupling) and the second coil element L1b is preferably coupled to the fourth coil element L2b in phase (the subtractive polarity coupling).

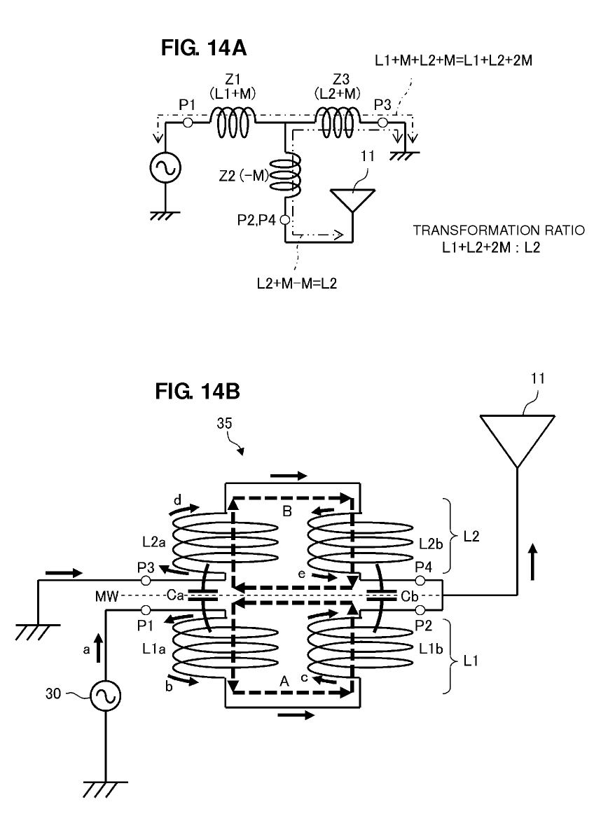

FIG. 14A shows a transformation ratio of the transformer having a high degree of coupling 35 and negative inductance components connected to the antenna on the basis of the equivalent circuit shown in FIG. 13B. FIG. 14B is a diagram in which various arrows indicating how the magnetic field coupling and the electric field coupling are performed are added to the circuit in FIG. 13B.

As shown in FIG. 14A, the transformer having a high degree of coupling is a transformer-type circuit in which the first inductance element L1 is tightly coupled to the second inductance element L2 via a mutual inductance M. The transformer-type circuit is capable of being equivalently converted into a T-shaped circuit including three inductance elements Z1, Z2, and Z3. Among the inductance elements Z1, Z2, and Z3, the inductance element Z2 is connected to the antenna element 11 to offset the positive inductance component of the antenna element 11 with the pseudo negative inductance (−M) of the inductance element Z2.

As shown in FIG. 14B, when current is supplied from the power feed circuit in a direction shown by an arrow a, the current flows through the first coil element L1a in a direction shown by an arrow b and the current flows through the coil element L1b in a direction shown by an arrow c. The currents define a magnetic flux (a magnetic flux passing through the closed magnetic circuit) shown by an arrow A in FIG. 14B.

Since the coil element L1a is lined with the coil element L2a, a magnetic field caused by the current b flowing through the coil element L1a is coupled to the coil element L2a to cause an induced current d to flow through the coil element L2a in a direction opposite to the direction of the current b. Similarly, since the coil element L1b is lined with the coil element L2b, a magnetic field caused by the current c flowing through the coil element L1b is coupled to the coil element L2b to cause an induced current e to flow through the coil element L2b in a direction opposite to the direction of the current c. The currents define a magnetic flux passing through the closed magnetic circuit, as shown by an arrow B in FIG. 14B.

Since the closed magnetic circuit of the magnetic flux A occurring in the first inductance element L1 including the coil elements L1a and L1b is independent of the closed magnetic circuit of the magnetic flux B occurring in the second inductance element L2 including the coil elements L1b and L2b, the equivalent magnetic barrier MW occurs between the first inductance element L1 and the second inductance element L2.

The coil element L1a is coupled to the coil element L2a also via the electric field. Similarly, the coil element L1b is coupled to the coil element L2b also via the electric field. Accordingly, when alternating current flows through the coil element L1a and the coil element L1b, the current is excited in the coil element L2a and the coil element L2b by the electric field coupling. Capacitors Ca and Cb in FIG. 14B symbolically denote the coupling capacitances for the electric field coupling.

When the alternating current flows through the first inductance element L1, the direction of the current flowing through the second inductance element L2 due to the coupling via the magnetic field coincides with the direction of the current flowing through the second inductance element L2 due to the coupling via the electric field. Accordingly, the first inductance element L1 and the second inductance element L2 are tightly coupled to each other via both the magnetic field and the electric field. In other words, it is possible to propagate the radio-frequency energy with a significantly reduced loss.

The transformer having a high degree of coupling 35 may also be referred to as a circuit configured such that, when the alternating current flows through the first inductance element L1, the direction of the current flowing through the second inductance element L2 due to the coupling via the magnetic field coincides with the direction of the current flowing through the second inductance element L2 due to the coupling via the electric field.

Equivalent conversion of the transformer having a high degree of coupling 35 results in the circuit shown in FIG. 14A. Specifically, the added inductance between the power feed circuit and the ground is equal to L1+M+L2+M=L1+L2+2M, as shown by an alternate long and short dash line in FIG. 14A. The added inductance between the antenna element and the ground is equal to L2+M−M=L2, as shown by a double dotted chain line in FIG. 14A. In other words, the transformation ratio in the transformer having a high degree of coupling is equal to L1+L2+2M:L2, so that it is possible to configure the transformer having a high degree of coupling with high transformation ratio.

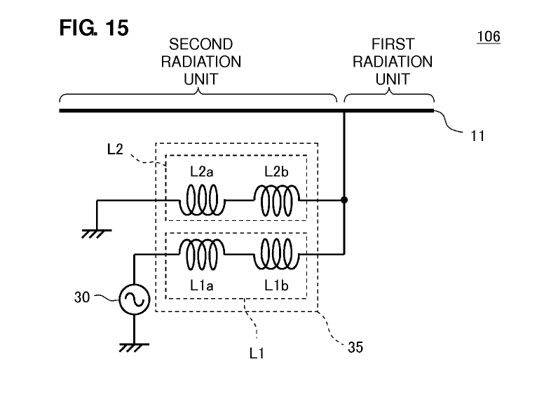

FIG. 15 is a circuit diagram of the antenna apparatus 106 supporting multiband operation. The antenna apparatus 106 is preferably for use in a multiband-supporting mobile radio communication system (the 800-MHz band, the 900-MHz band, the 1,800-MHz band, and the 1,900-MHz band) supporting the GSM mode and the CDMA mode, for example. The antenna element 11 preferably is a branched monopole antenna.

### Seventh Preferred Embodiment

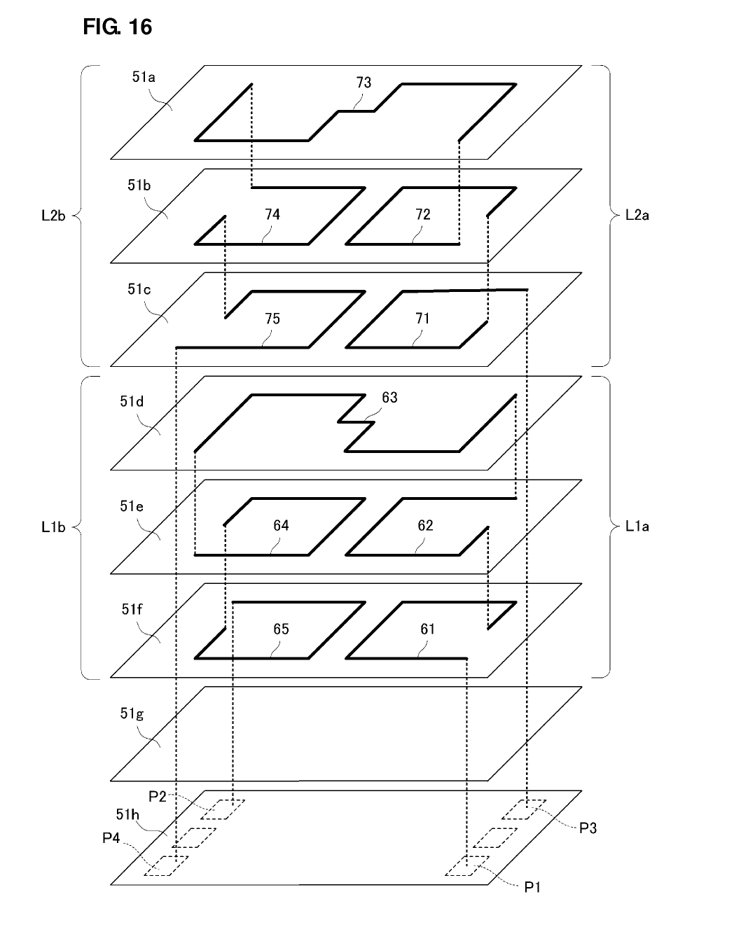

FIG. 16 shows exemplary conductor patterns of layers in a case in which the transformer having a high degree of coupling 35 according to a seventh preferred embodiment is provided in a multilayer board. Each layer is preferably defined by a magnetic sheet. Although the conductor pattern of each layer is provided on the rear surface of the magnetic sheet in the direction shown in FIG. 16, each conductor pattern is represented by a solid line. Although each linear conductor pattern has a certain line width, the linear conductor pattern is represented by the simple solid line in FIG. 16.

In the range shown in FIG. 16, the conductor pattern is provided on the rear surface of the base layer 51a, the conductor pattern 72 and a conductor pattern 74 are provided on the rear surface of the base layer 51b, and the conductor pattern 71 and a conductor pattern 75 are provided on the rear surface of the base layer 51c. The conductor pattern 63 is provided on the rear surface of the base layer 51d, the conductor patterns 62 and 64 are provided on the rear surface of the base layer 51e, and the conductor patterns 61 and 65 are provided on the rear surface of the base layer 51f. The conductor pattern 66 is provided on the rear surface of the base layer 51g and the ports P1, P2, P3, and P4 are provided on the rear surface of a base layer 51h. Dotted lines that vertically extend in FIG. 16 denote via electrodes that connects the conductor patterns to each other between the layers. Although these via electrodes are practically cylindrical electrodes each having a certain diameter, the via electrodes are represented by the simple dotted lines in FIG. 16.

Referring to FIG. 16, the right half of the conductor pattern 63 and the conductor patterns 61 and 62 define the first coil element L1a. The left half of the conductor pattern 63 and the conductor patterns 64 and 65 define the second coil element L1b. The right half of the conductor pattern 73 and the conductor patterns 71 and 72 define the third coil element L2a. The left half of the conductor pattern 73 and the conductor patterns 74 and 75 define the fourth coil element L2b. The winding axis of each of the coil elements L1a, L1b, L2a, and L2b is directed to the lamination direction of the multilayer board.

The winding axis of the first coil element L1a is juxtaposed with the winding axis of the second coil element L1b in a different manner. Similarly, the winding axis of the third coil element L2a is juxtaposed with the winding axis of the fourth coil element L2b in a different manner. The winding range of the first coil element L1a is at least partially overlaid or overlapped with that of the third coil element L2a in a plan view and the winding rage of the second coil element L1b is at least partially overlaid or overlapped with that of the fourth coil element L2b in a plan view. In the example in FIG. 16, the winding range of the first coil element L1a substantially coincides with that of the third coil element L2a in a plan view and the winding rage of the second coil element L1b substantially coincides with that of the fourth coil element L2b in a plan view. The conductor patterns each having a figure-of-eight configuration define the four coil elements in the above manner.

Each layer may be defined of a dielectric sheet, for example. However, a magnetic sheet having high relative permeability can be used to further increase the coupling coefficient between the coil elements.

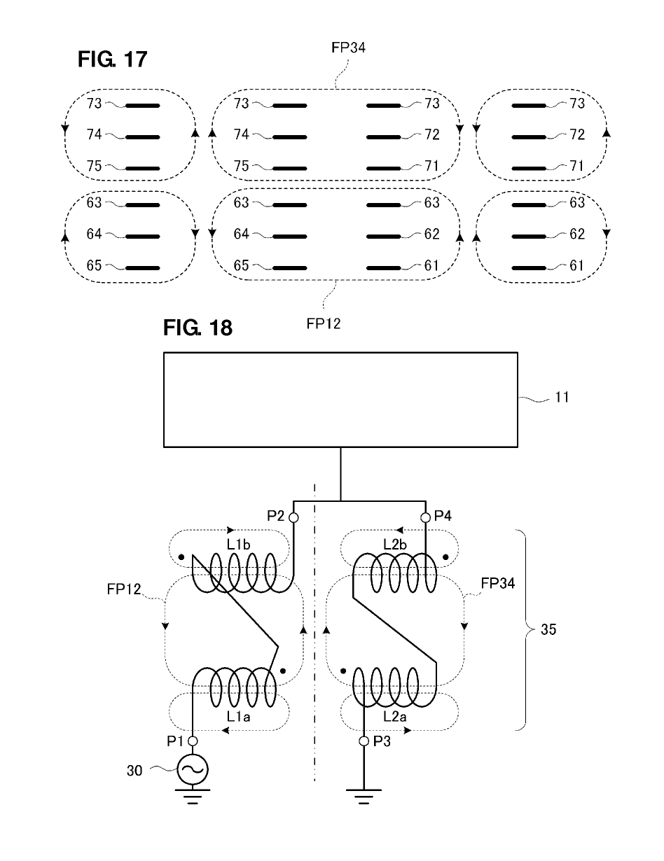

FIG. 17 shows main magnetic fluxes passing through the coil elements including the conductor patterns formed on the respective layers of the multilayer board shown in FIG. 16. A magnetic flux FP12 passes through the first coil element L1a including the conductor patterns 61 to 63 and the second coil element L1b including the conductor patterns 63 to 65. A magnetic flux FP34 passes through the third coil element L2a including the conductor patterns 71 to 73 and the fourth coil element L2b including the conductor patterns 73 to 75.

FIG. 18 shows the relationship of the magnetic coupling between the four coil elements L1a, L1b, L2a, and L2b of the transformer having a high degree of coupling 35 according to the seventh preferred embodiment. As shown in FIG. 18, the first coil element L1a and the second coil element L1b are wound such that the first coil element L1a and the second coil element L1b define a first closed magnetic circuit (a loop indicated by the magnetic flux FP12), and the third coil element L2a and the fourth coil element L2b are wound such that the third coil element L2a and the fourth coil element L2b define a second closed magnetic circuit (a loop indicated by the magnetic flux FP34). The four coil elements L1a, L1b, L2a, and L2b are wound in the above manner such that the direction of the magnetic flux FP12 passing through the first closed magnetic circuit is opposite to that of the magnetic flux FP34 passing through the second closed magnetic circuit. A straight double dotted chain line in FIG. 18 represents a magnetic barrier preventing the two magnetic fluxes FP12 and FP34 from being coupled to each other. The magnetic barrier occurs between the coil elements L1a and L2a and between the coil elements L1b and L2b in the above manner.

### Eighth Preferred Embodiment

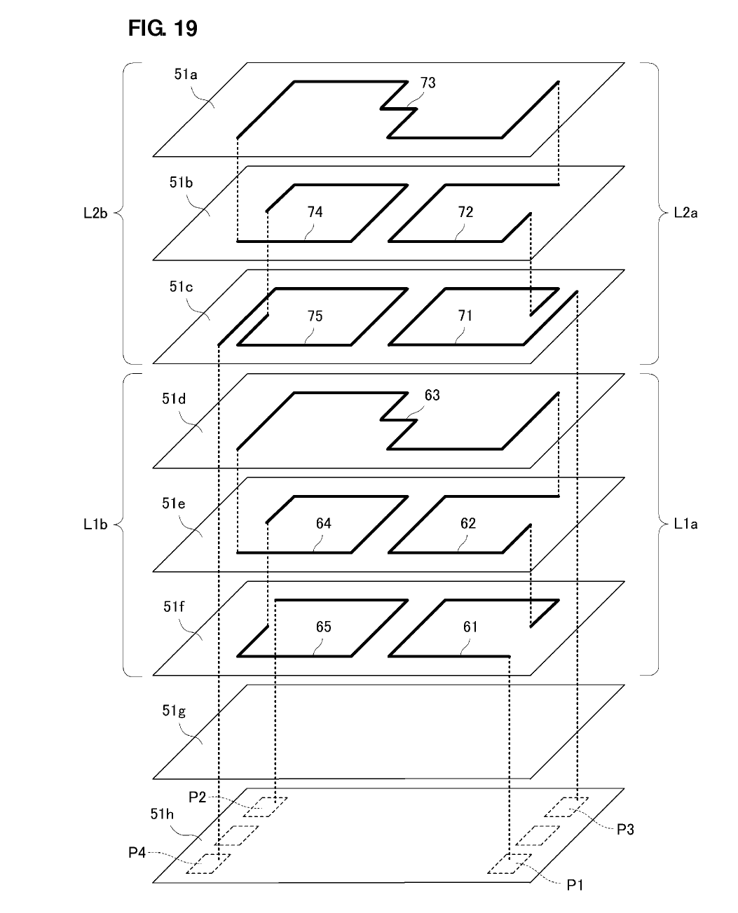

FIG. 19 shows the configuration of a transformer having a high degree of coupling according to an eighth preferred embodiment. Exemplary conductor patterns of layers in a case in which the transformer having a high degree of coupling is provided in a multilayer board are shown in FIG. 19. Although the conductor pattern of each layer is provided on the rear surface of the magnetic sheet in the direction shown in FIG. 19, each conductor pattern is represented by a solid line. Although each linear conductor pattern has a certain line width, the linear conductor pattern is represented by the simple solid line in FIG. 19.

In the range shown in FIG. 19, the conductor pattern is provided on the rear surface of the base layer 51a, the conductor patterns 72 and 74 are provided on the rear surface of the base layer 51b, and the conductor patterns 71 and 75 are provided on the rear surface of the base layer 51c. The conductor pattern 63 is provided on the rear surface of the base layer 51d, the conductor patterns 62 and 64 are provided on the rear surface of the base layer 51e, and the conductor patterns 61 and 65 are provided on the rear surface of the base layer 51f. The conductor pattern 66 is provided on the rear surface of the base layer 51g and the ports P1, P2, P3, and P4 are provided on the rear surface of the base layer 51h. Dotted lines that vertically extend in FIG. 19 denote via electrodes that connects the conductor patterns to each other between the layers. Although these via electrodes are practically cylindrical electrodes each having a certain diameter, the via electrodes are represented by the simple dotted lines in FIG. 19.

Referring to FIG. 19, the right half of the conductor pattern 63 and the conductor patterns 61 and 62 define the first coil element L1a. The left half of the conductor pattern 63 and the conductor patterns 64 and 65 define the second coil element L1b. The right half of the conductor pattern 73 and the conductor patterns 71 and 72 define the third coil element L2a. The left half of the conductor pattern 73 and the conductor patterns 74 and 75 define the fourth coil element L2b.

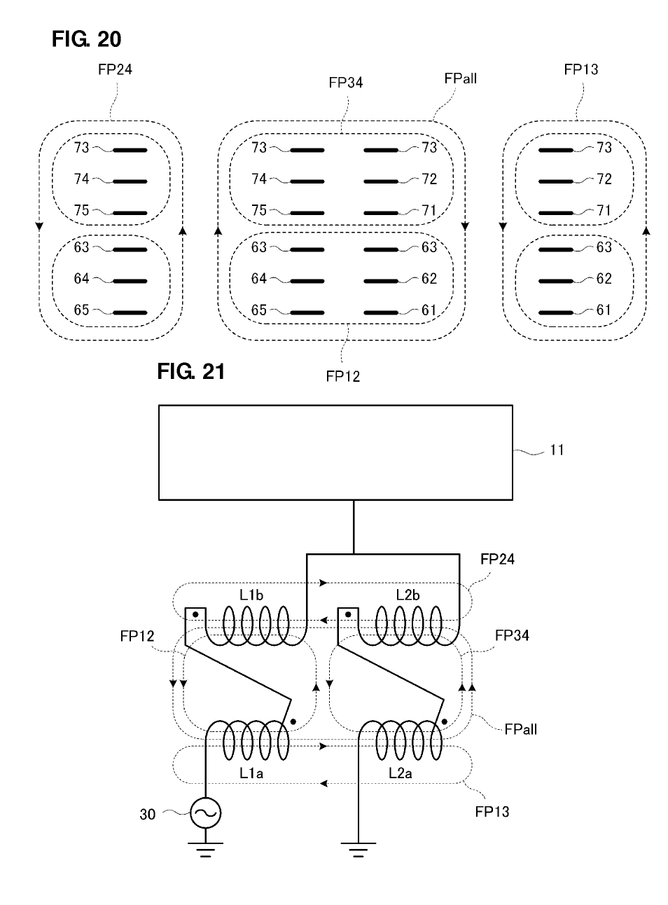

FIG. 20 shows main magnetic fluxes passing through the coil elements including the conductor patterns provided on the respective layers of the multilayer board shown in FIG. 19. FIG. 21 shows the relationship of the magnetic coupling between the four coil elements L1a, L1b, L2a, and L2b of the transformer having a high degree of coupling according to the eighth preferred embodiment. The closed magnetic circuit including the first coil element L1a and the second coil element L1b is provided, as shown by the magnetic flux FP12, and the closed magnetic circuit including the third coil element L2a and the fourth coil element L2b is provided, as shown by the magnetic flux FP34. In addition, a closed magnetic circuit including the first coil element L1a and the third coil element L2a is provided, as shown by a magnetic flux FP13, and a closed magnetic circuit including the second coil element L1b and the fourth coil element L2b is provided, as shown by a magnetic flux FP24. Furthermore, a closed magnetic circuit FPall including the four coil elements L1a, L1b, L2a, and L2b is also provided.

Since the inductance values of the coil elements L1a and L1b and the inductance values of the coil elements L2a and L2b are made small due to the coupling between the coil elements L1a and L1b and the coupling between the coil elements L2a and L2b, respectively, also in the configuration of the eighth preferred embodiment, the transformer having a high degree of coupling of the eighth preferred embodiment also has the same effects as those of the transformer having a high degree of coupling 35 of the sixth preferred embodiment.

### Ninth Preferred Embodiment

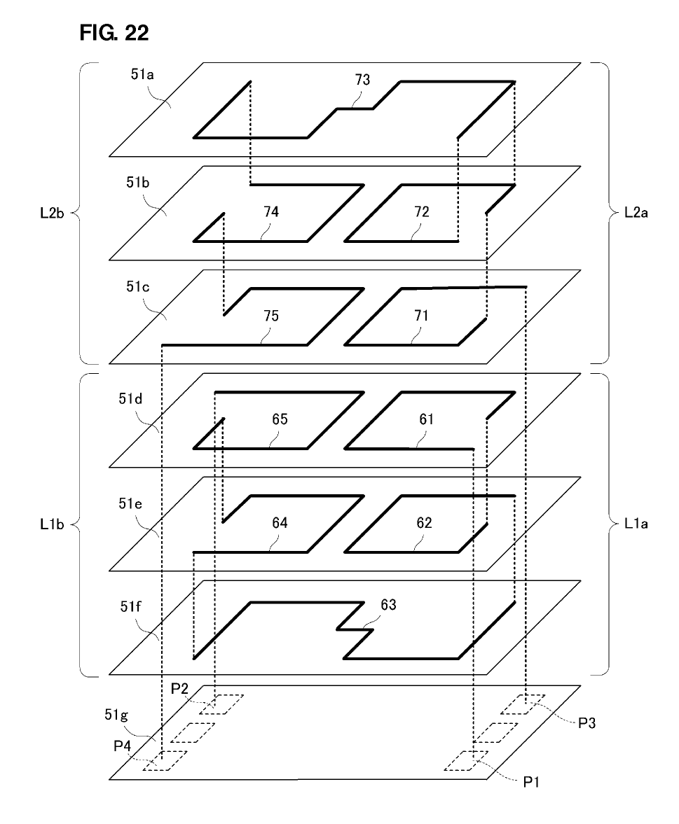

FIG. 22 shows exemplary conductor patterns of the respective layers of a transformer having a high degree of coupling according to a ninth preferred embodiment provided in a multilayer board. Each layer is preferably defined by a magnetic sheet, for example. Although the conductor pattern of each layer is provided on the rear surface of the magnetic sheet in the direction shown in FIG. 22, each conductor pattern is represented by a solid line. Although each linear conductor pattern has a certain line width, the linear conductor pattern is represented by the simple solid line in FIG. 22.

In the range shown in FIG. 22, the conductor pattern is provided on the rear surface of the base layer 51a, the conductor patterns 72 and 74 are provided on the rear surface of the base layer 51b, and the conductor patterns 71 and 75 are provided on the rear surface of the base layer 51c. The conductor patterns 61 and 65 are provided on the rear surface of the base layer 51d, the conductor patterns 62 and 64 are provided on the rear surface of the base layer 51e, and the conductor pattern 63 is provided on the rear surface of the base layer 51f. The ports P1, P2, P3, and P4 are provided on the rear surface of the base layer 51g. Dotted lines that vertically extend in FIG. 22 denote via electrodes that connects the conductor patterns to each other between the layers. Although these via electrodes are practically cylindrical electrodes each having a certain diameter, the via electrodes are represented by the simple dotted lines in FIG. 22.

Referring to FIG. 22, the right half of the conductor pattern 63 and the conductor patterns 61 and 62 define the first coil element L1a. The left half of the conductor pattern 63 and the conductor patterns 64 and 65 define the second coil element L1b. The right half of the conductor pattern 73 and the conductor patterns 71 and 72 define the third coil element L2a. The left half of the conductor pattern 73 and the conductor patterns 74 and 75 define the fourth coil element L2b.

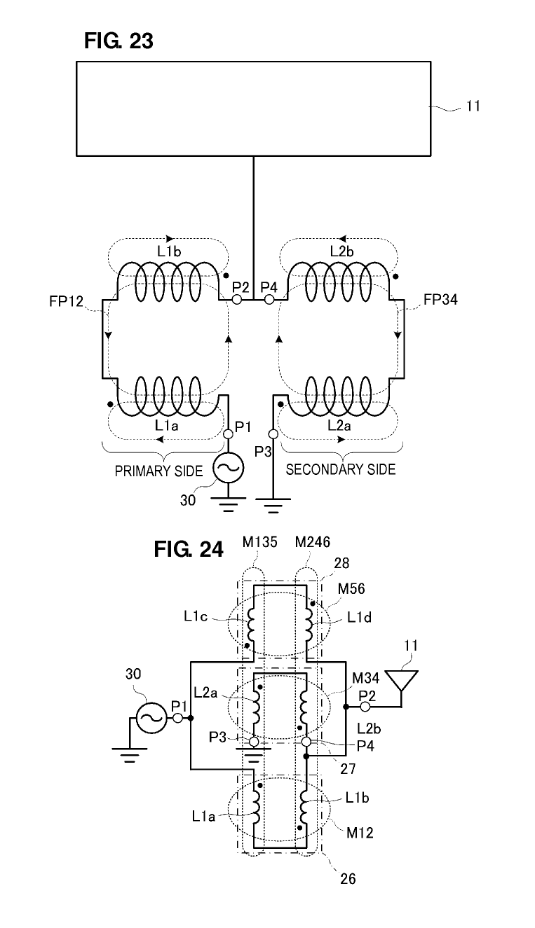

FIG. 23 shows the relationship of the magnetic coupling between the four coil elements L1a, L1b, L2a, and L2b of the transformer having a high degree of coupling according to the ninth preferred embodiment. As shown in FIG. 23, the first coil element L1a and the second coil element L1b define the first closed magnetic circuit (a loop indicated by the magnetic flux FP12). The third coil element L2a and the fourth coil element L2b define the second closed magnetic circuit (a loop indicated by the magnetic flux FP34). The direction of the magnetic flux FP12 passing through the first closed magnetic circuit is opposite to that of the magnetic flux FP34 passing through the second closed magnetic circuit.

Provided that the first coil element L1a and the second coil element L1b are represented as a “primary side” and the third coil element L2a and the fourth coil element L2b are represented as a “secondary side”, the power feed circuit is connected to the end of the primary side close to the secondary side, as shown in FIG. 23, and the voltage at the primary side near the secondary side is increased. Accordingly, the electric field coupling between the coil element L1a and the coil element L2a is increased to increase the current caused by the electric field coupling.

Since the inductance values of the coil elements L1a and L1b and the inductance values of the coil elements L2a and L2b are made small due to the coupling between the coil elements L1a and L1b and the coupling between the coil elements L2a and L2b, respectively, also in the configuration of the ninth preferred embodiment, the transformer having a high degree of coupling of the ninth preferred embodiment also has the same effects as those of the transformer having a high degree of coupling 35 of the sixth preferred embodiment.

### Tenth Preferred Embodiment

FIG. 24 is a circuit diagram of a transformer having a high degree of coupling according to a tenth preferred embodiment. The transformer having a high degree of coupling includes a first series circuit 26 connected between the power feed circuit 30 and the antenna element 11, a third series circuit 28 connected between the power feed circuit 30 and the antenna element 11, and a second series circuit 27 connected between the antenna element 11 and the ground.

In the first series circuit 26, the first coil element L1a is connected in series to the second coil element L1b. In the second series circuit 27, the third coil element L2a is connected in series to the fourth coil element L2b. In the third series circuit 28, a fifth coil element L1c is connected in series to a sixth coil element L1d.

Referring to FIG. 24, an enclosure M12 represents the coupling between the coil elements L1a and L1b, an enclosure M34 represents the coupling between the coil elements L2a and L2b, and an enclosure M56 represents the coupling between the coil elements L1c and L1d. An enclosure M135 represents the coupling between the coil elements L1a, L2a, and L1c. Similarly, an enclosure M246 represents the coupling between the coil elements L1b, L2b, and L1d.

In the tenth preferred embodiment, the coil elements L2a and L2b defining the second inductance element are arranged so as to be sandwiched between the coil elements L1a, L1b, L1c, and L1d defining the first inductance element to suppress the stray capacitor occurring between the second inductance element and the ground. The suppression of such a capacitance component that does not contribute the radiation allows the radiation efficiency of the antenna to be improved.

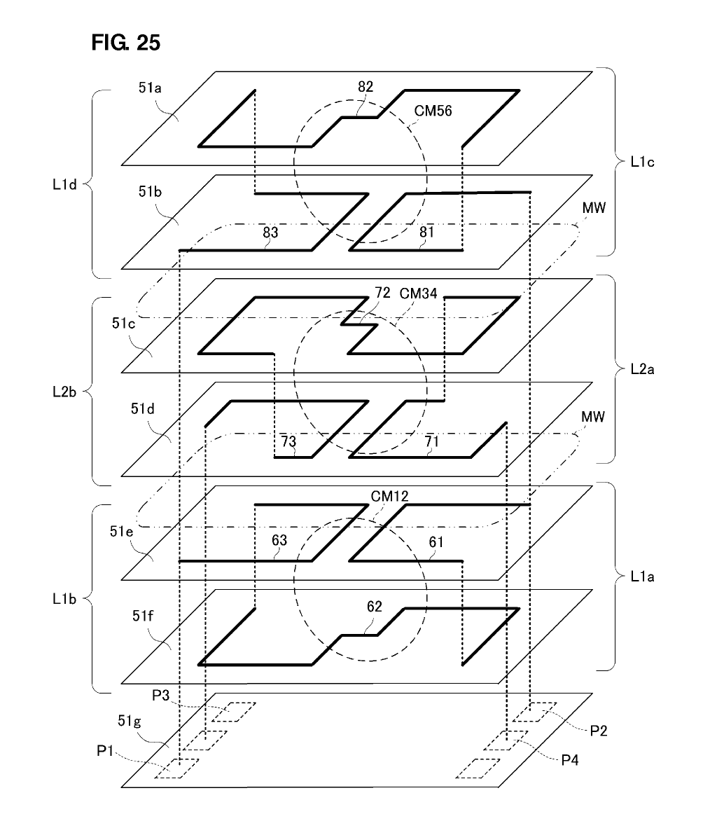

FIG. 25 shows exemplary conductor patterns of layers in a case in which the transformer having a high degree of coupling according to the tenth preferred embodiment is provided in a multilayer board. Each layer is preferably defined by a magnetic sheet, for example. Although the conductor pattern of each layer is provided on the rear surface of the magnetic sheet in the direction shown in FIG. 25, each conductor pattern is represented by a solid line. Although each linear conductor pattern has a certain line width, the linear conductor pattern is represented by the simple solid line in FIG. 25.

In the range shown in FIG. 25, a conductor pattern 82 is provided on the rear surface of the base layer 51a, conductor patterns 81 and 83 are provided on the rear surface of the base layer 51b, and the conductor pattern 72 is provided on the rear surface of the base layer 51c. The conductor patterns 71 and 73 are provided on the rear surface of the base layer 51d, the conductor patterns 61 and 63 are provided on the rear surface of the base layer 51e, and the conductor pattern 62 is provided on the rear surface of the base layer 51f. The ports P1, P2, P3, and P4 are provided on the rear surface of the base layer 51g. Dotted lines that vertically extend in FIG. 25 denote via electrodes that connects the conductor patterns to each other between the layers. Although these via electrodes are practically cylindrical electrodes each having a certain diameter, the via electrodes are represented by the simple dotted lines in FIG. 25.

Referring to FIG. 25, the right half of the conductor pattern 62 and the conductor pattern 61 define the first coil element L1a. The left half of the conductor pattern 62 and the conductor pattern 63 define the second coil element L1b. The conductor pattern 71 and the right half of the conductor pattern define the third coil element L2a. The left half of the conductor pattern 72 and the conductor pattern 73 define the fourth coil element L2b. The conductor pattern 81 and the right half of the conductor pattern 82 define the fifth coil element L1c. The left half of the conductor pattern 82 and the conductor pattern 83 define the sixth coil element L1d.

Broken-line ellipses represent the closed magnetic circuits in FIG. 25. A closed magnetic circuit CM12 links to the coil elements L1a and L1b. A closed magnetic circuit CM34 links to the coil elements L2a and L2b. A closed magnetic circuit CM56 links to the coil elements L1c and L1d. The first coil element L1a and the second coil element L1b define the first closed magnetic circuit CM12, the third coil element L2a and the fourth coil element L2b define the second closed magnetic circuit CM34, and the fifth coil element L1c and the sixth coil element L1d define the third closed magnetic circuit CM56 in the above manner. Planes represented by double dotted chain lines in FIG. 25 represent two magnetic barriers MW that equivalently occur because the coil elements L1a and L2a are coupled to each other and the coil elements L2a and L1c are coupled to each other such that the magnetic fluxes in opposite directions occur between the three closed magnetic circuits and the coil elements L1b and L2b are coupled to each other and the coil elements L2b and L1d are coupled to each other such that the magnetic fluxes in opposite directions occur between the three closed magnetic circuits. In other words, the magnetic flux of the closed magnetic circuit including the coil elements L1a and L1b, the magnetic flux of the closed magnetic circuit including the coil elements L2a and L2b, and the magnetic flux of the closed magnetic circuit including the coil elements L1c and L1d are contained by the two magnetic barriers MW.

As described above, the second closed magnetic circuit CM34 is sandwiched between the first closed magnetic circuit CM12 and the third closed magnetic circuit CM56 in the lamination direction. With this structure, the second closed magnetic circuit CM34 is sandwiched between the two magnetic barriers to be sufficiently contained (the effect of the containment is improved). In other words, it is possible to cause the transformer having a high degree of coupling to operate as a transformer having a very large coupling coefficient.

Accordingly, it is possible to increase the space between the closed magnetic circuits CM12 and CM34 and the space between the closed magnetic circuits CM34 and CM56 to some extent. Provided that a circuit in which the series circuit including the coil elements L1a and L1b is connected in parallel to the series circuit including the coil elements L1c and L1d is referred to as a primary side circuit and the series circuit including the coil elements L2a and L2b is referred to as a secondary side circuit, the increase in the space between the closed magnetic circuits CM12 and CM34 and the space between the closed magnetic circuits CM34 and CM56 allows the capacitance occurring between the first series circuit 26 and the second series circuit 27 and the capacitance occurring between the second series circuit 27 and the third series circuit 28 to be decreased. In other words, the capacitance component of an LC resonant circuit defining the frequency of a self-resonance point is decreased.

In addition, according to the tenth preferred embodiment, since the first series circuit 26 including the coil elements L1a and L1b is connected in parallel to the third series circuit 28 including the coil elements L1c and L1d, the inductance component of the LC resonant circuit defining the frequency of the self-resonance point is decreased.

Both the capacitance component and the inductance component of the LC resonant circuit defining the frequency of the self-resonance point are decreased in the above manner, so that the frequency of the self-resonance point can be set to a high frequency sufficiently apart from the frequency band that is used.

### Eleventh Preferred Embodiment

An exemplary configuration to make the frequency of the self-resonance point of the transformer higher than the frequency shown in the seventh to ninth preferred embodiments with a configuration different from that in the tenth preferred embodiment is shown in an eleventh preferred embodiment.

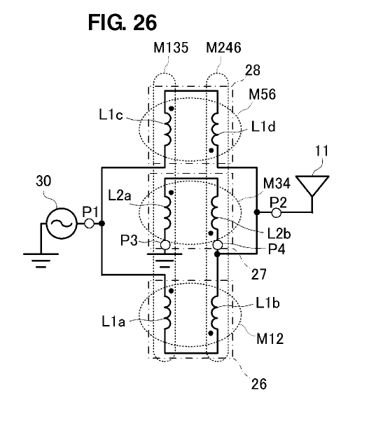

FIG. 26 is a circuit diagram of a transformer having a high degree of coupling according to the eleventh preferred embodiment. The transformer having a high degree of coupling includes the first series circuit 26 connected between the power feed circuit 30 and the antenna element 11, the third series circuit 28 connected between the power feed circuit 30 and the antenna element 11, and the second series circuit 27 connected between the antenna element 11 and the ground.

In the first series circuit 26, the first coil element L1a is connected in series to the second coil element L1b. In the second series circuit 27, the third coil element L2a is connected in series to the fourth coil element L2b. In the third series circuit 28, the fifth coil element L1c is connected in series to the sixth coil element L1d.

Referring to FIG. 26, the enclosure M12 represents the coupling between the coil elements L1a and L1b, the enclosure M34 represents the coupling between the coil elements L2a and L2b, and the enclosure M56 represents the coupling between the coil elements L1c and L1d. The enclosure M135 represents the coupling between the coil elements L1a, L2a, and L1c. Similarly, the enclosure M246 represents the coupling between the coil elements L1b, L2b, and L1d.

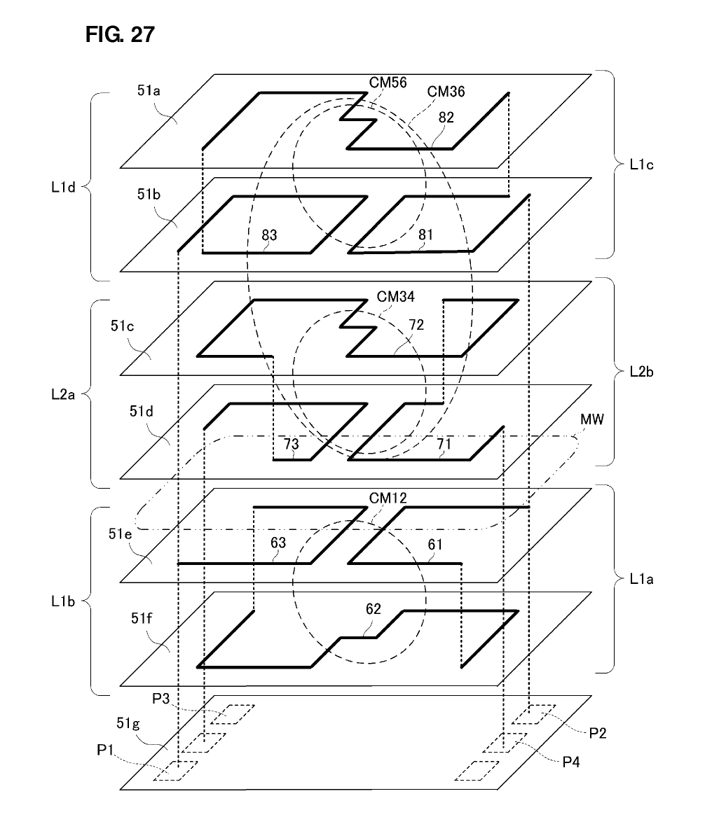

FIG. 27 shows exemplary conductor patterns of layers in a case in which the transformer having a high degree of coupling according to the eleventh preferred embodiment is provided in a multilayer board. Each layer is preferably defined by a magnetic sheet, for example. Although the conductor pattern of each layer is provided on the rear surface of the magnetic sheet in the direction shown in FIG. 27, each conductor pattern is represented by a solid line. Although each linear conductor pattern has a certain line width, the linear conductor pattern is represented by the simple solid line in FIG. 27.

The transformer having a high degree of coupling in FIG. 27 differs from the transformer having a high degree of coupling shown in FIG. 25 in the polarity of the coil elements L1c and L1d including the conductor patterns 81, 82, and 83. In the example in FIG. 27, a closed magnetic circuit CM36 links to the coil elements L2a, L1c, L1d, and L2b. Accordingly, no equivalent magnetic barrier occurs between the coil elements L2a and L2b and the coil elements L1c and L1d. The remaining configuration is preferably the same as that in the tenth preferred embodiment.

According to the eleventh preferred embodiment, the closed magnetic circuit CM36 occurs, in addition to the closed magnetic circuits CM12, CM34, and CM56 shown in FIG. 27, to absorb the magnetic flux caused by the coil elements L2a and L2b into the magnetic flux caused by the coil elements L1c and L1d. Accordingly, the magnetic flux is difficult to leak out also in the configuration in the eleventh preferred embodiment. As a result, it is possible to cause the transformer having a high degree of coupling to operate as a transformer having a very large coupling coefficient.

Both the capacitance component and the inductance component of the LC resonant circuit defining the frequency of the self-resonance point are decreased also in the eleventh preferred embodiment, so that the frequency of the self-resonance point can be set to a high frequency sufficiently apart from the frequency band that is used.

### Twelfth Preferred Embodiment

Another exemplary configuration to make the frequency of the self-resonance point of the transformer higher than the frequency shown in the seventh to ninth preferred embodiments with a configuration different from those in the tenth preferred embodiment and the eleventh preferred embodiment is shown in a twelfth preferred embodiment.

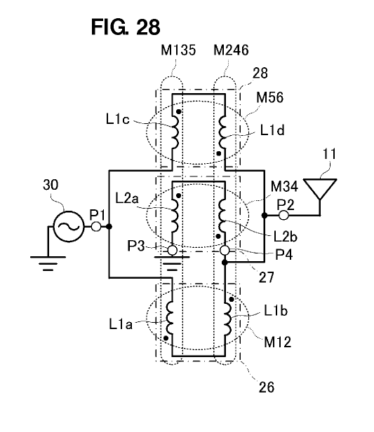

FIG. 28 is a circuit diagram of a transformer having a high degree of coupling according to the twelfth preferred embodiment. The transformer having a high degree of coupling includes the first series circuit 26 connected between the power feed circuit 30 and the antenna element 11, the third series circuit 28 connected between the power feed circuit 30 and the antenna element 11, and the second series circuit 27 connected between the antenna element 11 and the ground.

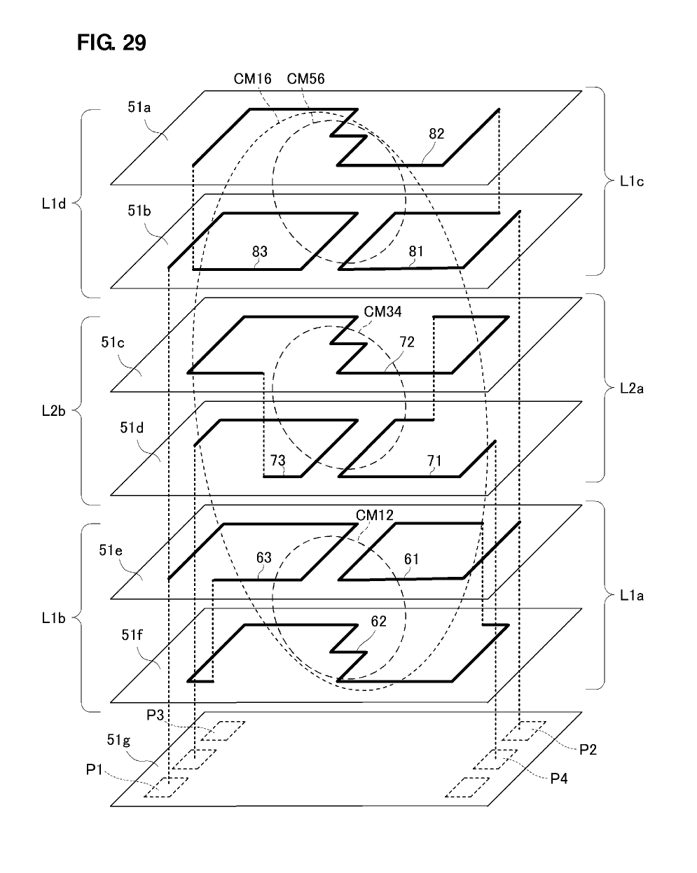

FIG. 29 shows exemplary conductor patterns of layers in a case in which the transformer having a high degree of coupling according to the twelfth preferred embodiment is provided in a multilayer board. Each layer is preferably defined by a magnetic sheet, for example. Although the conductor pattern of each layer is provided on the rear surface of the magnetic sheet in the direction shown in FIG. 29, each conductor pattern is represented by a solid line. Although each linear conductor pattern has a certain line width, the linear conductor pattern is represented by the simple solid line in FIG. 29.

The transformer having a high degree of coupling in FIG. 29 differs from the transformer having a high degree of coupling shown in FIG. 25 in the polarity of the coil elements L1a and L1db including the conductor patterns 61, 62, and 63 and the polarity of the coil elements L1c and L1d including the conductor patterns 81, 82, and 83. In the example in FIG. 29, a closed magnetic circuit CM16 links to all the coil elements L1a to L1d, L2a, and L2b. Accordingly, no equivalent magnetic barrier occurs in this case. The remaining configuration is preferably the same as those in the tenth preferred embodiment and the eleventh preferred embodiment.

According to the twelfth preferred embodiment, the occurrence of the closed magnetic circuit CM16, in addition to the closed magnetic circuits CM12, CM34, and CM56 shown in FIG. 29, makes the magnetic flux caused by the coil elements L1a to L1d difficult to leak out. As a result, it is possible to cause the transformer having a high degree of coupling to operate as a transformer having a large coupling coefficient.

Both the capacitance component and the inductance component of the LC resonant circuit defining the frequency of the self-resonance point are decreased also in the twelfth preferred embodiment, so that the frequency of the self-resonance point can be set to a high frequency sufficiently apart from the frequency band that is used.

### Thirteenth Preferred Embodiment

Examples of a communication terminal apparatus are shown in a thirteenth preferred embodiment.

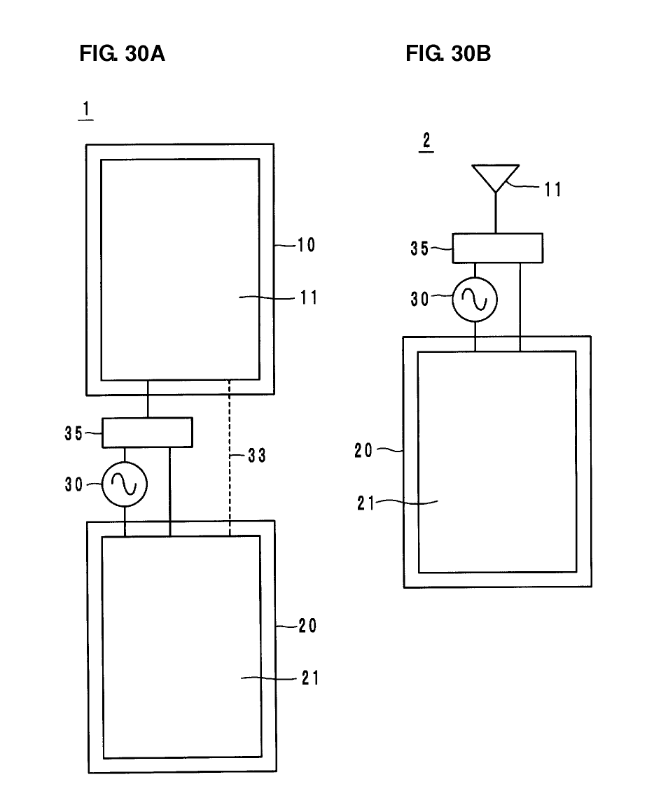

FIG. 30A shows the configuration of a communication terminal apparatus of a first example of the thirteenth preferred embodiment. FIG. 30B shows the configuration of a communication terminal apparatus of a second example of the thirteenth preferred embodiment. These communication terminal apparatuses are, for example, for use as terminals for reception of radio-frequency signals (e.g., about 470 MHz to about 770 MHz) in one-segment partial reception service for mobile terminals such as cellular phones (commonly called One seg).

A communication terminal apparatus 1 shown in FIG. 30A includes a first casing 10, which is a lid portion, and a second casing 20, which is a main body portion. The first casing 10 is connected to the second casing 20 in a foldable manner or a slidable manner. A first radiation element 11, which also functions as a ground plate, is provided in the first casing 10. A second radiation element 21, which also functions as a ground plate, is provided in the second casing 20. The first and second radiation elements 11 and 21 are each preferably defined by a conductive film, which is a thin film such as a metal foil or a thick film such as conductive paste. The first and second radiation elements 11 and 21 receive differential power supply from the power feed circuit 30 to achieve the performance substantially similar to that of a dipole antenna. The power feed circuit 30 includes signal processing circuits, such as a radio-frequency (RF) circuit and a baseband circuit.

The inductance value of the transformer having a high degree of coupling 35 is preferably smaller than the inductance value of a connection line 33 connecting the two radiation elements 11 and 21. This is because it is possible to reduce the effect of the inductance value of the connection line 33 concerning frequency characteristics in the above case.

A communication terminal apparatus 2 shown in FIG. 30B includes the first radiation element 11 as a single antenna. Various antenna elements including a chip antenna, a sheet metal antenna, and a coil antenna can be used as the first radiation element 11. For example, a linear conductor provided along the inner periphery or the outer periphery of the casing 10 may be used as this antenna element. The second radiation element 21 also functions as the ground plate for the second casing 20 and various antennas may be used as the second radiation element 21, as in the first radiation element 11. The communication terminal apparatus 2 is a straight terminal, which is not a foldable or slidable terminal. The second radiation element 21 may not sufficiently function as the radiator and the first radiation element 11 may behave like a so-called monopole antenna.

One end of the power feed circuit 30 is connected to the second radiation element 21 and the other end thereof is connected to the first radiation element 11 via the transformer having a high degree of coupling 35. The first radiation element is connected to the second radiation element 21 via the connection line 33. The connection line 33 functions as a connection line for electronic devices (not shown) installed in each of the first and second casings 10 and 20. The connection line 33 behaves as an inductance element for the radio-frequency signals but does not directly affect the performance of the antenna.

The transformer having a high degree of coupling 35 is provided between the power feed circuit 30 and the first radiation element 11 and stabilizes the radio-frequency signals transmitted from the first and second radiation elements 11 and or the radio-frequency signals received by the first and second radiation elements 11 and 21. Accordingly, the frequency characteristics of the radio-frequency signals are stabilized without the effects of the shapes of the first radiation element 11 and the second radiation element 21, the shapes of the first casing 10 and the second casing 20, and/or the status of arrangement of adjacent elements. In particular, although the impedances of the first and second radiation elements 11 and 21 are likely to be varied depending on the opening-closing state of the first casing 10, which is the lid portion, with respect to the second casing 20, which is the main body portion, in the foldable and slidable communication terminal apparatuses, the provision of the transformer having a high degree of coupling 35 allows the frequency characteristics of the radio-frequency signals to be stabilized. Specifically, the transformer having a high degree of coupling 35 can serve the function of adjusting the frequency characteristics, such as setting of the center frequency, setting of the pass band width, and setting of impedance matching, which are important matters for design of the antenna. Accordingly, it is sufficient to mainly consider the directivity and the gain in the antenna element itself, thus facilitating the design of the antenna.

The transformer having a high degree of coupling of various preferred embodiments of the present invention is applicable to radio-frequency electronic circuits, such as voltage step-up and step-down circuits, current transformation and shunt circuits, and balance-unbalance conversion circuits, for example, in addition to the impedance conversion circuits described above. In addition, the radio-frequency electronic circuits are applicable to electronic devices, such as mobile communication terminals, Radio Frequency Identification (RFID) tags and reader-writers, televisions, and personal computers, for example.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A transformer comprising:
a first inductance element; and
a second inductance element coupled to the first inductance element; wherein
the first inductance element is coupled to the second inductance element via a magnetic field and an electric field; and
when alternating current flows through the first inductance element, a direction of current flowing through the second inductance element due to the coupling via the magnetic field coincides with a direction of current flowing through the second inductance element due to the coupling via the electric field.

2. The transformer according to claim 1, wherein, when alternating current flows through the first inductance element, the direction of current flowing through the second inductance element is a direction along which a magnetic barrier occurs between the first inductance element and the second inductance element.

3. The transformer according to claim 1, wherein the first inductance element includes a first coil element and a second coil element, and the first coil element is connected in series to the second coil element and winding patterns of conductors of the first coil element and the second coil element are arranged to define a closed magnetic circuit.

4. The transformer according to claim 1, wherein the second inductance element includes a third coil element and a fourth coil element, and the third coil element is connected in series to the fourth coil element and winding patterns of conductors of the third coil element and the fourth coil element are arranged to define a closed magnetic circuit.

5. The transformer according to claim 1, wherein
the first inductance element includes a first coil element and a second coil element, and the first coil element is connected in series to the second coil element and winding patterns of conductors of the first coil element and the second coil element are arranged to define a closed magnetic circuit;
the second inductance element includes a third coil element and a fourth coil element, and the third coil element is connected in series to the fourth coil element and winding patterns of conductors of the third coil element and the fourth coil element are arranged to define a closed magnetic circuit; and
the first coil element and the third coil element are arranged such that an opening of the first coil element opposes an opening of the third coil element, and the second coil element and the fourth coil element are arranged such that an opening of the second coil element opposes an opening of the fourth coil element.

6. The transformer according to claim 1, wherein the first inductance element and the second inductance element including conductor patterns are arranged in a multilayer body in which a plurality of dielectric or magnetic layers is laminated, and the first inductance element is coupled to the second inductance element in the multilayer body.

7. An electronic circuit comprising:
a transformer including a first inductance element and a second inductance element coupled to the first inductance element; wherein
the first inductance element is coupled to the second inductance element via a magnetic field and an electric field; and
when alternating current flows through the first inductance element, a direction of current flowing through the second inductance element due to the coupling via the magnetic field coincides with a direction of current flowing through the second inductance element due to the coupling via the electric field;
a primary side circuit connected to the first inductance element; and
a secondary side circuit connected to the second inductance element.

8. An electronic device comprising:
a transformer including a first inductance element and a second inductance element coupled to the first inductance element; wherein
the first inductance element is coupled to the second inductance element via a magnetic field and an electric field; and
when alternating current flows through the first inductance element, a direction of current flowing through the second inductance element due to the coupling via the magnetic field coincides with a direction of current flowing through the second inductance element due to the coupling via the electric field;
a primary side circuit connected to the first inductance element;
a secondary side circuit connected to the second inductance element; and
a circuit that transfers a signal or power between the primary side circuit and the secondary side circuit via the transformer.
